(19) United States
(12) Patent Application Publication
(10) Pub. No.: US 2026/0292980 A1
(43) Pub. Date: Sep. 24, 2026

(54) CIRCUIT BOARD

(71) Applicant: LG INNOTEK CO., LTD., Seoul (KR)

(72) Inventors: Jae Woong CHOI, Seoul (KR); Yu Lim Choe, Seoul (KR); Bung Suek Oh, Seoul (KR)

(21) Appl. No.: 19/570,339

(22) Filed: Mar. 18, 2026

(30) Foreign Application Priority Data
Mar. 21, 2025 (KR) 10-2025-0036679

(51) Int. Cl. H05K 1/11

(52) U.S. Cl. CPC H05K 1/111; H05K 2201/09427

(57) ABSTRACT

The present embodiment relates to a circuit board. The circuit board according to one aspect of the present invention comprises: an insulating layer; a pad portion disposed on the insulating layer; and a bonding portion disposed on the pad portion, wherein a concave portion of concave shape is disposed on the upper surface of the bonding portion, and the concave portion is disposed eccentrically relative to the center of the bonding portion.

### CROSS-REFERENCE TO RELATED APPLICATION

This application claims priority under 35 U.S.C. § 119 to Korean Application No. 10-2025-0036679 filed on Mar. 21, 2025, whose entire disclosure is hereby incorporated by reference.

### TECHNICAL FIELDS

The teachings in accordance with exemplary and non-limiting embodiments of the present invention relate generally to a circuit board.

### BACKGROUND ARTS

Electronic devices incorporated with electronic components include various active and passive circuit elements, which may be integrated onto semiconductor chips or dies. Furthermore, the semiconductor chips or dies may be provided in the form of electronic packages mounted onto substrates including circuit wiring, such as printed circuit boards (PCBs).

Meanwhile, when mounting a semiconductor chip onto a printed circuit board and electrically connecting it, a flip chip connection structure utilizing a connection structure is widely applied in electronic packages. For example, a flip chip connection structure using bumps is advantageous for realizing a stacked structure of various forms of semiconductor chips. Furthermore, the flip chip connection structure facilitates the adoption of multiple connection structures to secure a large number of input/output (I/O) terminals.

Among the methods for forming such connection structures is the Solder-On-Pad (SOP) method. The SOP method manufactures the connection structure by printing metallic paste or mounting ball-shaped solder onto the connection pads on the printed circuit board surface exposed by the solder mask pattern, then forming spherical solder joints through reflow, utilizing the surface tension effect.

In line with the recent trend towards higher integration in semiconductor packages, the number of terminals on semiconductor chips is also increasing, leading to more complex wiring. Consequently, achieving fine pitch for the bonding pads connecting to the semiconductor chip disposed on the circuit board is a critical factor affecting the quality of the circuit board.

To achieve fine pitch, a method of reducing the horizontal width of each bonding area may be considered. However, in this case, as the horizontal width of the bonding areas decreases, they become more vulnerable to shear stress, leading to a problem where the durability of the bonding areas themselves is compromised.

### SUMMARY OF INVENTION

### Technical Subjects

The present invention is intended to provide a circuit board that facilitates the realization of fine pitch through a reduction in the horizontal width of the bonding portion, while simultaneously enhancing the durability of the bonding portion itself.

### Technical Solutions

A circuit board according to one embodiment may comprise: an insulating layer; a pad portion disposed on the insulating layer; a protective layer disposed on the pad portion; and a bonding portion disposed on the pad portion, wherein the protective layer includes a hole penetrated in the vertical direction, wherein the bonding portion includes a through portion disposed in the hole and a protrusion disposed on the through portion and having a width greater than the width of the through portion, and the width of the through portion is within the range of 50% or more to 90% or less of the width of the protrusion.

A circuit board according to another embodiment may comprise: a build-up insulating portion including multiple insulating layers stacked in the vertical direction; a pad portion disposed on the build-up insulating portion; a protective layer disposed on the pad portion; a bonding portion disposed on the protective layer and connected to the pad portion by penetrating the protective layer; and a plurality of via electrodes disposed on the underside of the pad portion and penetrating at least a portion of the build-up insulating portion, wherein the bonding portion includes a through-hole overlapping the protective layer in the horizontal direction and a protrusion disposed on the protective layer, wherein the horizontal width of the through-hole is at least 50% and at most 90% of the horizontal width of the protrusion, and at least some of the plurality of via electrodes are vertically overlapped with the pad portion, the protective layer, and the protrusion.

### Advantageous Effects

According to the present embodiments, the surface treatment of the protective layer enables increased bonding strength with the bonding portion, and consequently, the horizontal width of the bonding portion can be reduced compared to conventional methods, offering the advantage of facilitating the realization of fine pitches.

Furthermore, by penetrating the insulating layer and overlapping the bonding portion vertically through the via hole, the shear strength of the bonding portion can be enhanced to thereby present another advantage.

### BRIEF DESCRIPTION OF DRAWINGS

FIG. 1 is a cross-sectional view of a circuit board according to an embodiment of the present invention.

FIG. 2 is an enlarged view illustrating the arrangement structure of the bonding portion on the insulating layer according to an embodiment of the present invention.

FIGS. 3 and 4 are photographs of the bonding interface of the protective layer of the bonding portion according to an embodiment of the present invention.

FIG. 5 is a diagram illustrating the bonding strength of the bonding portion on the circuit board according to an embodiment of the present invention.

FIG. 6 is an image of the bonding interface between the bonding portion and the protective layer according to a comparative example.

FIG. 7 is an illustration to explain the bonding strength of the bonding portion on the circuit board according to the comparative example.

FIG. 8 is a table illustrating the shapes of the bonding portions according to various widths of the through portions in an embodiment of the present invention.

FIG. 9 is a graph comparing the shear stress of the bonding portions according to FIG. 8.

FIG. 10 is a table comparing the shear stress of the bonding portion according to the presence or absence of the protective layer, the horizontal width of the protruding portion, the horizontal width of the through portion, the horizontal width of the second region, and the horizontal width of the pad portion.

FIG. 11 is a photograph of the fracture test results for the bonding portions D and E shown in FIG. 10.

FIG. 12 is a diagram illustrating the arrangement structure of the bonding portion and protrusion according to an embodiment of the present invention.

FIGS. 13 to 17 are diagrams illustrating various modified examples of the arrangement structure of the bonding portion and protrusion according to embodiments of the present invention.

FIG. 18 is a diagram illustrating the fracture surface of the bonding portion according to the number of protrusions overlapping perpendicularly with the through portion.

FIG. 19 is a diagram illustrating the shear strength of the bonding portion through the protrusions according to an embodiment of the present invention.

FIG. 20 is a graph illustrating the shear stress according to the number of protrusions overlapping perpendicularly with the through portion.

FIG. 21 is a cross-sectional view of a semiconductor package according to an embodiment of the present invention.

### BEST MODES

Hereinafter, the attached drawings are referred to in detail to explain the preferred embodiment of the present invention.

However, the technical idea of the present invention is not limited to the some embodiments described, but can be implemented in various different forms, and within the scope of the technical idea of the present invention, one or more of the components between the embodiments can be selectively combined or replaced.

In addition, the terms used in the embodiments of the present invention (including technical and scientific terms) can be interpreted to mean what a person with ordinary skill in the art would understand, unless explicitly defined and described, and generally understood by a person with ordinary skill in the art. Generally used terms, such as those defined in dictionaries, can be interpreted in the context of the relevant technology.

Furthermore, the terms used in the embodiments of the present invention are intended to explain the embodiments and are not intended to limit the invention. In this specification, the singular form may include the plural form unless otherwise specified in the text, and when described as ‘A and (and/and) B, C, at least one (or more than one) of A, B, and C,’ it may include one or more of all combinations of A, B, and C.

In addition, terms such as 1, 2, A, B, (a), and (b) may be used to describe the components of the embodiments of the present invention. Such terms are intended only to distinguish the component from other components and are not limited by the nature, order, or sequence of the component.

And, if any component is described as being ‘connected’, ‘coupled’ or ‘attached’ to another component, that component may be directly connected, coupled or attached to that other component, as well as being ‘connected’, ‘coupled’ or ‘attached’ to another component that is between that component and that other component.

In addition, when it is stated that each component is formed or arranged ‘above or below’, the above or below includes not only the case where two components are directly in contact with each other, but also the case where one or more other components are formed or arranged between the two components. In addition, when it is expressed as ‘upper or lower’, it can include the meaning of the lower direction as well as the upper direction based on one component.

Furthermore, the expression that configuration A is disposed between configurations B and C must also be understood to include the meaning that configuration A is disposed such that at least part of it overlaps with configurations B and C in the horizontal and/or vertical directions.

Expressions referring to direction include horizontal direction and vertical direction, and the horizontal direction includes a first horizontal direction and a second horizontal direction perpendicular to the first horizontal direction. This corresponds to the first horizontal direction (X-axis), the second horizontal direction (Y-axis), and the vertical direction (Z-axis) in a Cartesian coordinate system. The meaning of overlapping along the horizontal direction must also include overlapping along the first horizontal direction and/or overlapping along the second horizontal direction.

Furthermore, the meaning that configuration A is exposed from configuration B should be understood as meaning that it is exposed from configuration B, not that it is exposed from the product claimed by configuration A. That is, when it is stated that configuration A is exposed from configuration B, it should be understood to mean that configuration A is not exposed from the product claimed by configuration C, which is other than configuration B.

Furthermore, where it is stated that configuration A “contacts” configuration B, this may encompass not only direct “contact” between the configurations themselves, but also “contact” mediated by another configuration situated between them. Therefore, where it is intended that configuration A should only be understood as being in “direct contact” with configuration B, it shall be stated as being in “direct contact”.

Furthermore, where it is stated that configuration A is “covered” by configuration B, this should be understood to mean that configuration A is covered by configuration B, such that at least some part of configuration A is covered by configuration B, taking into account the functionality and purpose being addressed. Unless specifically stated otherwise, it should not be understood that the entirety of configuration A is covered by configuration B.

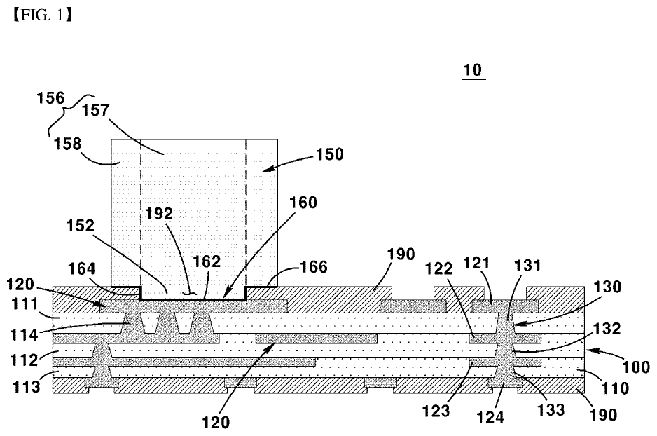

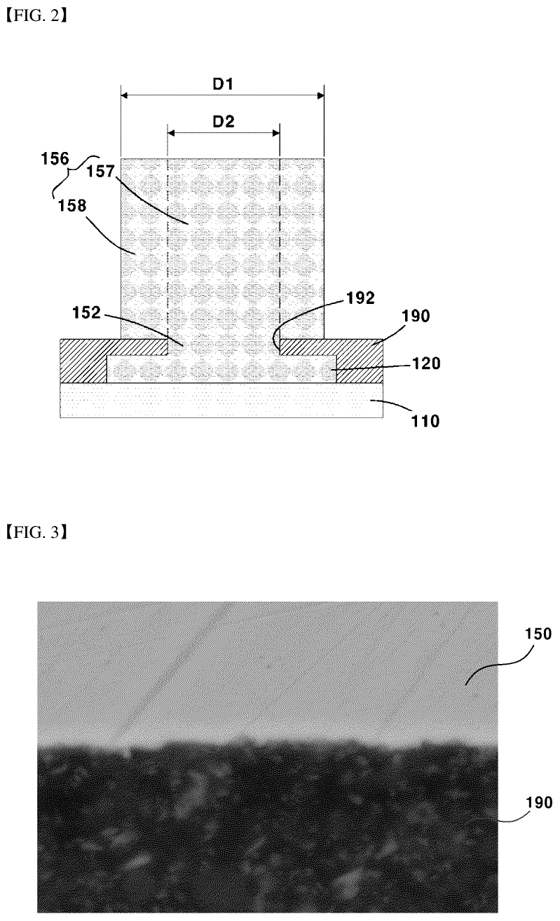

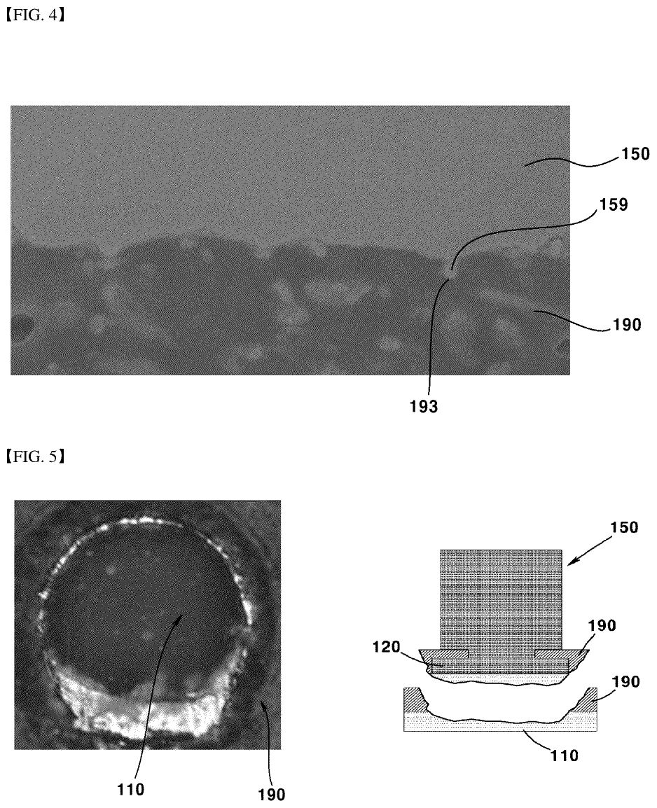

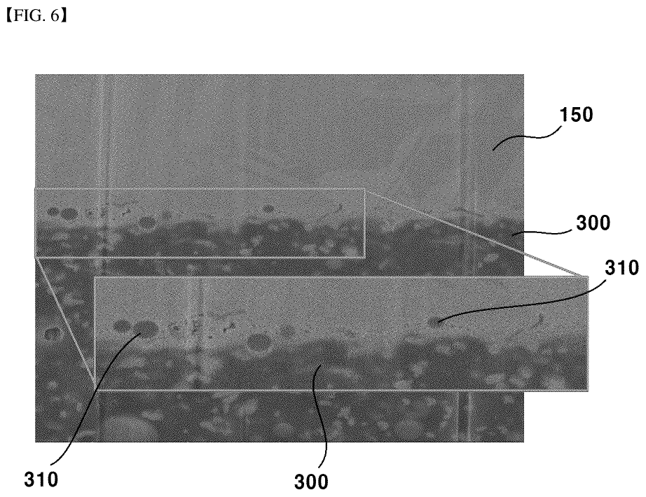

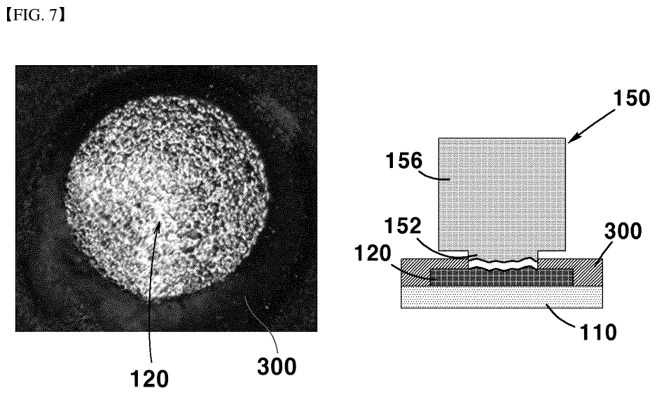

FIG. 1 is a cross-sectional view of a circuit board according to an embodiment of the present invention, FIG. 2 is an enlarged view illustrating the arrangement structure of the bonding portion on the insulating layer according to an embodiment of the present invention, FIGS. 3 and 4 are photographs of the bonding interface of the protective layer of the bonding portion according to an embodiment of the present invention, FIG. 5 is a diagram illustrating the bonding strength of the bonding portion on the circuit board according to an embodiment of the present invention, FIG. 6 is an image of the bonding interface between the bonding portion and the protective layer according to a comparative example, and FIG. 7 is an illustration to explain the bonding strength of the bonding portion on the circuit board according to the comparative example.

Referring to FIGS. 1 to 7, the circuit board (10) according to an embodiment of the present invention may comprise a build-up structure (100) and a protective layer (190).

The build-up structure (100) may include a build-up insulating portion, a plurality of wiring portions (120), a plurality of via portions (130), and a bonding portion (150).

The build-up structure (100) may include a build-up insulating portion. The build-up insulating portion may include a plurality of insulating layers (110) stacked in a vertical direction. The plurality of insulating layers (110) may be stacked in the vertical direction. For example, the plurality of insulating layers may include a third insulating layer (113), a second insulating layer (112) disposed on the third insulating layer (113), and a first insulating layer (111) disposed on the second insulating layer (112). The number of multiple insulating layers constituting the build-up structure (100) is exemplary; the circuit board (10) may have a greater number of insulating layers stacked vertically.

The first to third insulating layers (111, 112, 113) may each be any insulating material, such as light-curable and/or thermosetting materials. Thermosetting insulating materials may include insulating materials in which inorganic and/or organic fillers are dispersed within a resin, such as ABF (Ajinomoto Build-up Film), a product released by Ajinomoto Co., Inc., and prepregs (PPG) containing glass fibers within the resin. Furthermore, the aforementioned resins may exemplarily be epoxy resin, bis-maleimide triazine resin (BT resin), phenolic resin, etc., and the inorganic and/or organic fillers may be provided by materials such as silica, plastics, etc. When an insulating resin is used as the core, it may include a reinforcing material provided by glass fiber or aramid fiber, etc. Where at least some of the insulating layers constituting the first to third insulating layers (111, 112, 113) are photo-curable insulators, at least some of the insulating layers constituting the first to third insulating layers (111, 112, 113) may each be PID (Photo Imageable Dielectric).

The circuit board (10) may comprise a protective layer (190). The protective layer (190) may include a first protective layer disposed on the surface of the first insulating layer (111) and a second protective layer disposed on the surface of the third insulating layer (113). The protective layer (190) can perform the function of preventing short circuits between solder when semiconductor devices are disposed on the surface of the circuit board (10) using materials such as solder, due to its low wettability with the solder. It can also prevent the problem of external contaminants penetrating the build-up structure and degrading reliability. The protective layer (190) may utilize a light-curable insulating material. Therefore, the protective layer (190) is provided as a solder resist, not the aforementioned ABF, PPG, BT resin, or PID. However, this is not limited to this, and as described above, it may be provided with various materials capable of performing the function of preventing solder-to-solder short circuits due to low wettability with solder.

The first protective layer may include holes (192) to expose wiring portions (121) disposed on the first insulating layer (111) in the vertical direction. The second protective layer may include holes to expose wiring portions (124) disposed on the surface of the third insulating layer (113) in the vertical direction of the circuit board (10).

The circuit board (10) may include a build-up wiring structure for conveying electrical signals and/or power to electronic devices such as semiconductor chips. The build-up wiring structure may include a plurality of wiring portions (120), a plurality of via portions (130), and bonding portions (150).

The plurality of wiring portions (120) may each be disposed on the surface of a plurality of insulating layers (110). Here, “disposed on the surface” may also include meaning that at least a portion of the multiple wiring sections (120) is embedded within each of the multiple insulating layers (110) or protective layers (190) and exposed externally from the surface. Furthermore, the surface of the multiple insulating layers (110) includes a one surface, the other surface, and the side surface between the one and the other surfaces. Here, the one surface of the insulating layer (110) may be understood as the upper surface, and the other surface of the insulating layer (110) may be understood as the lower surface. The meaning of the wiring portion (120) being disposed on the surface implies that it is disposed on at least one of the one surface, the other surface, or the side surface of the plural insulating layers (110). The structure may also comprise wiring portions (120) disposed on both the one surface and the other surface of some of the multiple insulating layers (110), while on other portions of the multiple insulating layers (110), wiring portions (120) are disposed only on either the one surface or the other surface.

The multiple wiring portions (120) may include a first wiring portion (121) disposed on the first insulating layer (111), a second wiring portion (122) disposed on a second insulating layer (112), a third wiring portion (123) disposed on a third insulating layer (113), and a fourth wiring portion (124) disposed on the lower surface of the third insulating layer (113). Among the plural wiring portions (120), the second wiring portion (122) and the third wiring portion (123) may, for example, have an ETS (Embedded Trace Substrate) structure to realize fine patterns. Specifically, the second wiring portion (122) and the third wiring portion (123) may be embedded within the second insulating layer (112) and the third insulating layer (113). Here, “embedded” means that at least part of the side surface of the wiring portion having the ETS structure is covered by the insulating layer (110). Recesses (concave portions) with a concave shape for the placement of the second wiring portion (122) and the third wiring portion (123) may be provided on the upper surface of the second insulating layer (112) and the upper surface of the third insulating layer (113), respectively.

Meanwhile, the first wiring portion (121) and the fourth wiring portion (124), disposed on the surface of the plurality of insulating layers (110), may also be referred to as the first pad portion and the second pad portion, respectively. Hereinafter, the first wiring portion (121) disposed on the insulating layer (110) shall be referred to as the pad portion (121) for the purposes of explanation.

The plurality of via portions (130) may be a metallic material disposed within via holes formed in each of the plurality of insulating layers (110) to connect a plurality of wiring portions (120) facing each other in the vertical direction. Here, the via holes vertically penetrate at least a portion of each of the plurality of insulating layers (110), and the via portions (130) may be disposed within the via holes.

A plurality of via portions (130) may include a first via portion (131) penetrating at least a portion of the first insulating layer (111), a second via portion (132) penetrating at least a portion of the second insulating layer (112), and a third via portion (133) penetrating at least a portion of the third insulating layer (113). The first via portion (131) may electrically connect the first wiring portion (121) and the second wiring portion (122). The second via portion (132) may electrically connect the second wiring portion (122) and the third wiring portion (123). The third via portion (133) may electrically connect the third wiring portion (123) and the fourth wiring portion (124).

The first to third via portions (131, 132, 133) may each have a shape wherein the horizontal width progressively increases in the direction from the first insulating layer (111) towards the third insulating layer (113). The vertical length of at least some of the plurality of via portions (130) may differ from the vertical length of the other via portions. For example, the vertical length of the first via portion (131) may be longer than the vertical length of the second via portion (132) or the third via portion (133).

The circuit board (10) may include a bonding portion (150). The bonding portion (150) may be disposed on top of the plurality of insulating layers (110). The bonding portion (150) may have a shape protruding above the circuit board (10), with at least a portion thereof penetrating the protective layer (190). The bonding portion (150) may be connected to the pad portion (121).

The bonding portion (150) may include a through portion (152) penetrating the protective layer (190) and a protrusion (156) protruding from the through portion (152) and disposed on the protective layer (190).

The through portion (152) may be disposed on the pad portion (121). The through portion (152) may be disposed to pass through the hole (192) in the protective layer (190). The through portion (152) may be disposed to overlap horizontally with the protective layer (190). The horizontal width (D2) of the through portion (152) may be smaller than the horizontal width of the pad portion (121) or the horizontal width (D1) of the protrusion (156). The horizontal width (D2) of the through portion (152) may be equal to the horizontal width of a hole (192). The vertical length of the through portion (152) may be shorter than the vertical length of the protrusion (156).

The protrusion (156) may be disposed on the through hole (152). The upper surface of the protrusion (156) may be bonded to a semiconductor chip. The horizontal width (D1) of the protrusion (156) may be greater than the horizontal width (D2) of the through hole (152). The horizontal width (D1) of the protrusion (156) may be smaller than the horizontal width of the pad portion (121). The vertical length of the protrusion (156) may be longer than the vertical length of the through hole (152).

The protrusion (156) may include a first region (157) vertically overlapping the hole (192) and the through portion (152) of the protective layer (190), and a second region (158) misaligned (offset) so as not to vertically overlap the hole (192) and the through portion (152). The second region (158) may be disposed on an external side of horizontal direction of the first region (157).

The circuit board (10) may include a seed layer (160) for forming the bonding portion (150). The bonding portion (150) may be formed by a plating method via the seed layer (160). The size of the grains constituting the seed layer (160) may be larger than the size of the grains constituting the bonding portion (150).

The seed layer (160) may include a first portion (162) disposed on the pad portion (121), a second portion (164) disposed on the inner wall of the hole (192) of the protective layer (190), and a third portion (166) disposed on the protective layer (190). The first portion (162) may be disposed to overlap perpendicularly with the first region (157) of the through portion (152) and the protruding portion (156). The third portion (166) may be disposed to overlap perpendicularly with the second region (158) of the protrusion (156). Thus, by means of an electroplating method through the first to third portions (162, 164, 166), a bonding portion (150) may be realized on the pad portion (121).

As shown in FIGS. 3 and 4, the surface of the protective layer (190) forming the bonding interface with the bonding portion (150) may be surface-treated. For example, the surface of the protective layer (190) to be bonded to the bonding portion (150) may be plasma-treated. Accordingly, as shown in FIG. 4, a concave portion (193) of a concave shape is formed on the surface of the protective layer (190) to be bonded to the bonding portion (150), and a protrusion (159) for bonding with the concave portion (193) may be disposed on the surface of the bonding portion (150). Consequently, during the formation process of the bonding portion (150) on the surface of the protective layer (190), a bonding structure is formed via the concave portion (193) and the protrusion (159), enabling the bonding of the bonding portion (150) to the surface of the protective layer (190) to be achieved robustly.

The concave portion (193) and protrusions (159) are each provided in plural numbers, as shown in FIGS. 3 and 4, and are disposed along the bonding interface between the protective layer (190) and the bonding portion (150). The shape of each of the plural concave portions (193) and the shape of each of the plural protrusions (159) may differ from one another. Here, the difference in shape may mean that the horizontal width and vertical length of each of the plural concave portions (193) and/or each of the plural protruding portions (159) are different.

FIG. 5 illustrates a fracture test of the bonding portion (150) bonded to the surface of the plasma-treated protective layer (190). When the bonding between the protective layer (190) and the bonding portion (150) is firmly established, when an external force is applied to separate the bonding portion (150) from the circuit board (10), it can be observed that a portion of the protective layer (190) and/or a portion of the insulating layer (110) separates together with the bonding portion (150). In this case, as illustrated on the left side of FIG. 5, the upper surface of the insulating layer (110) becomes exposed upwards through the fracture surface of the bonding portion (150) on the circuit board (10).

FIG. 6 shows an enlarged view of the bonding interface between the unplasma-treated protective layer (300) and the bonding portion (150). The protective layer (300) comprises a resin and a filler disposed within the resin. During the plating process for forming the bonding portion (150), filler (310) may become exposed from the surface of the protective layer (300). Consequently, the plating area may envelop the exposed filler (310) from the surface of the protective layer (300), potentially reducing the bonding affinity between the protective layer (300) and the bonding portion (150). Furthermore, the irregular surface of the protective layer (300) forming the bonding interface may cause plating defects, such as the formation of voids within the bonding portion (150).

FIG. 7 illustrates a fracture test of a bonding portion (150) bonded to the surface of a non-plasma-treated protective layer (300). Due to the reduced bonding strength with the bonding portion (150) caused by the filler (310) exposed from the surface of the protective layer (300), when an external force is applied to separate the bonding portion (150) on the circuit board (10), only the bonding portion (150) separates from the pad portion (120). That is, as illustrated on the left side of FIG. 7, the upper surface of the pad portion (120) becomes exposed upwards through the fracture surface of the bonding portion (150) on the circuit board (10).

Accordingly, in the embodiment, through surface treatment of the protective layer (190) that bonds with the bonding portion (150), the bonding strength between the bonding portion (150) and the protective layer (190) can be enhanced due to the structure wherein the filler is not exposed from the surface of the resin within the protective layer (190).

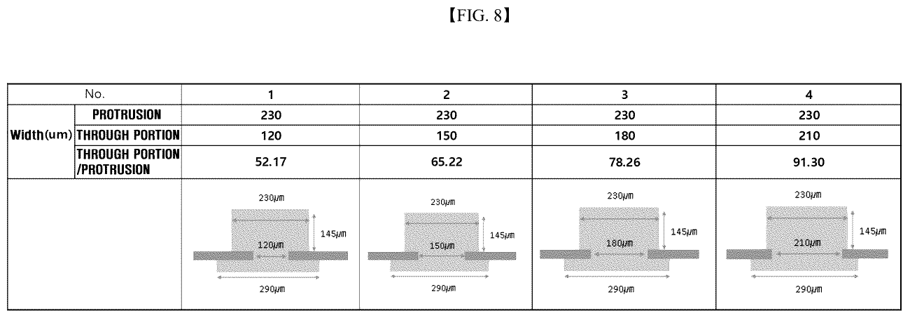

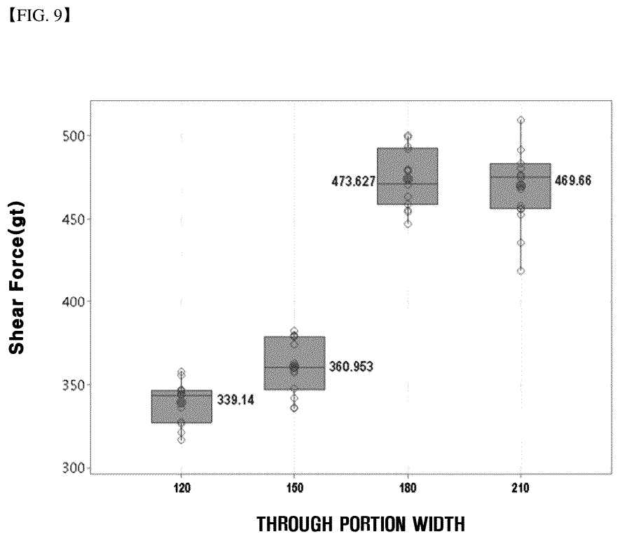

FIG. 8 is a table illustrating the shapes of bonding portions according to various widths of the through portion in accordance with an embodiment of the present invention, and FIG. 9 is a graph comparing the shear stress of the bonding portions according to FIG. 8.

Referring to FIG. 8, while fixing the horizontal width of the protrusion (156) at 230 μm, bonding portions (150) formed with the horizontal width of the through portion (152) set to 120 μm, 150 μm, 180 μm, and 210 μm are respectively illustrated as 1, 2, 3, and 4.

Referring to FIG. 9, it can be observed that as the horizontal width of the through portion (152) increases, the shear stress in the bonding portion (150) rises. This is due to an increase in the bonding area with the protective layer (190) and an increase in the durability of the bonding portion (150) itself. However, if the horizontal width of the through portion (152) exceeds 90% of the horizontal width of the protrusion (156), the effect of increasing shear stress becomes negligible. Furthermore, increasing the width of the through portion (152) may lead to an increase in the width of the hole (192) within the protective layer (190) and may also increase the amount of plating required to form the bonding portion (150). Furthermore, achieving fine pitch between multiple bonding portions (150) on the circuit board (10) may prove difficult. Therefore, it is desirable that the horizontal width of the through portion (152) according to the embodiment be 90% or less of the horizontal width of the protrusion (157).

Moreover, if the horizontal width of the through portion (152) is less than 50% of the horizontal width of the protrusion (156), it will possess a shear stress of 300 gf or less, which is the fracture strength of the bonding portion (150). Therefore, according to the embodiment, it is desirable that the horizontal width of the through portion (152) is 50% or more and 90% or less of the horizontal width of the protrusion (156).

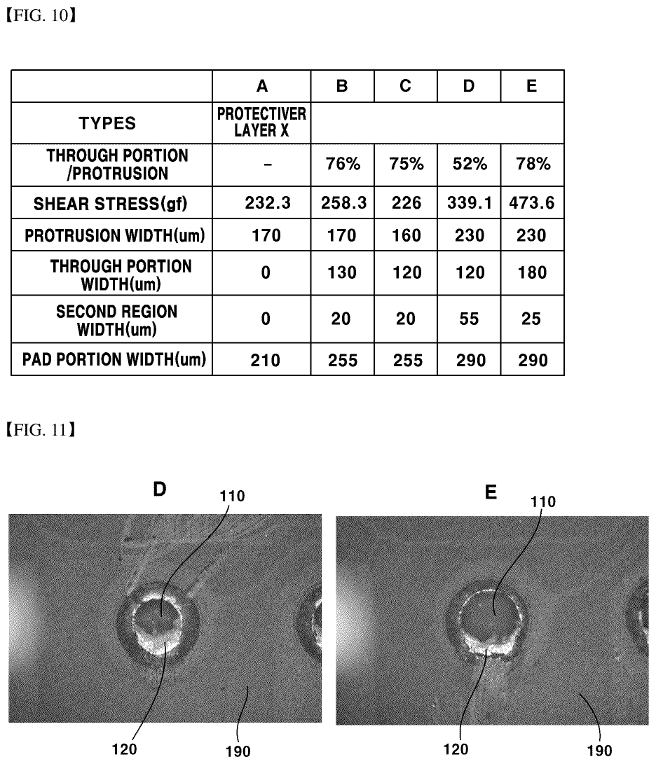

FIG. 10 is a table comparing the shear stress of the bonding portion according to the presence or absence of a protective layer, the horizontal width of the protrusion, the horizontal width of the through portion, the horizontal width of the second region, and the horizontal width of the pad portion. FIG. 11 is a photograph of the fracture test results for bonding portions D and E shown in FIG. 10.

Referring to FIG. 10, it can be observed that bonding portion A, which lacks a protective layer (190), exhibits lower shear stress compared to bonding portions B, C, D, and E, which possess a protective layer (190). Specifically, when comparing bonding portion A and bonding portion B, which have the same horizontal width of the protrusion (156), it can be confirmed that the shear stress of the bonding portion (150) improves by more than 10% due to the presence of the protective layer (190). This effect arises from the enhanced bonding strength of the bonding portion (150) via the protective layer (190) on the circuit board (10).

Moreover, as previously stated, when the horizontal width of the protrusion (156) is identical, the shear stress increases as the horizontal width of the through portion (152) becomes larger. That is, as shown in FIG. 11, for bonding portions D and E, where the horizontal width of the protrusion (156) is identical, it can be observed from the fracture surface obtained in the fracture test that bonding portion E, which has a relatively larger horizontal width of the through portion (152), exposes a relatively larger area of the insulating layer (110) surface onto the circuit board (10) compared to bonding portion D. Here, the fact that the exposed area of the insulating layer (110) is larger signifies, as described in FIG. 5, that the bonding strength between the bonding portion (150) and the protective layer (190), and between the bonding portion (150) and the pad portion (120), is greater.

Moreover, when the horizontal width of the through portion (152) is identical, the greater the horizontal width of the protrusion (156), the greater the shear stress may become. For bonding portions C and D with identical horizontal widths of the through portion (152), as shown in the table of FIG. 10, it can be confirmed that bonding portion D, having a larger horizontal width, exhibits higher shear stress compared to bonding portion C. However, when the horizontal width of the protrusion (156) is large, it is disadvantageous for achieving fine pitch between multiple bonding portions (150) on the circuit board (10). Therefore, it is desirable for the horizontal width of the protrusion (156) to be less than or equal to the horizontal width of the pad portion (121).

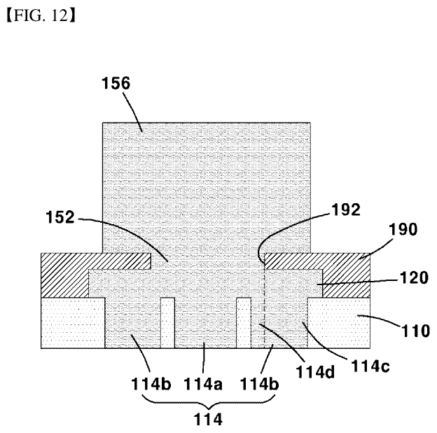

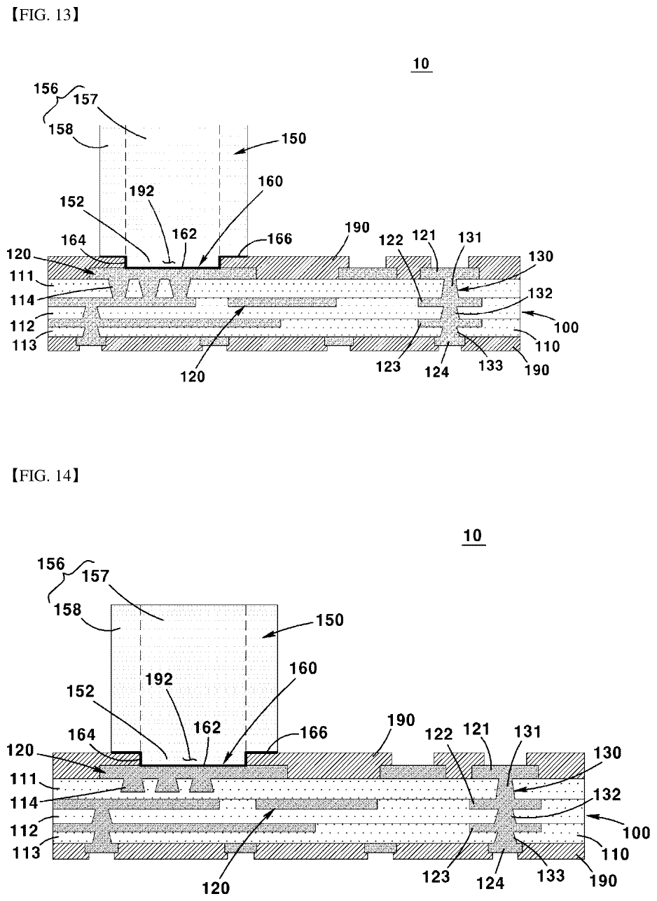

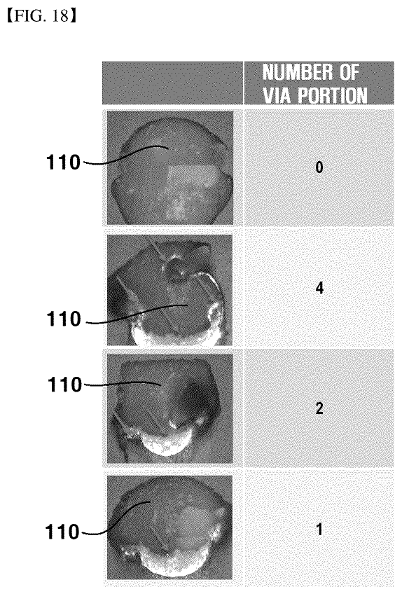

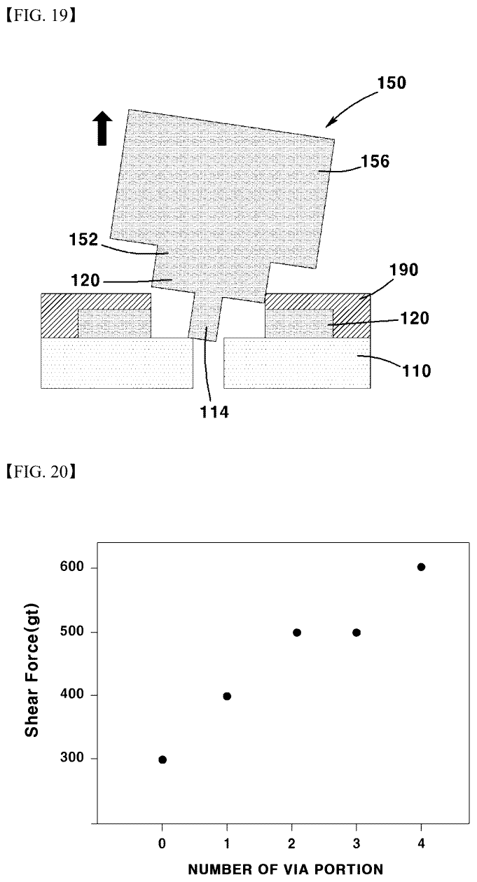

FIG. 12 is a diagram illustrating the arrangement structure of the bonding portion and protrusion according to an embodiment of the present invention, FIGS. 13 to 17 are drawings illustrating various modified examples of the arrangement structure of the bonding portion and protruding portion according to embodiments of the present invention, FIG. 18 is a drawing illustrating the fracture surface of the bonding portion according to the number of protruding portions vertically overlapping the through portion, FIG. 19 is a drawing illustrating the shear strength of the bonding portion through the protrusion according to embodiments of the present invention, and FIG. 20 is a graph illustrating the shear stress according to the number of protrusions vertically overlapping the through portion.

Referring to FIGS. 1 to 20, the circuit board (10) may comprise an insulating layer (110), a pad portion (120) disposed on the insulating layer (110), a protective layer (190) disposed on the insulating layer (110), and a bonding portion (150) disposed on the pad portion (120) and penetrating the protective layer (190). The pad portion (120) disposed on the insulating layer (110) may be electrically connected via wiring, such as a circuit line, to another pad portion disposed on the insulating layer (110) and spaced apart horizontally from the pad portion (120).

Furthermore, the pad portion (120) may include a protrusion (114) vertically penetrating at least a portion of the build-up insulating portion on the lower surface. The protrusion (114) may be electrically connected to a build-up wiring portion embedded within the build-up insulating portion, but is not necessarily limited thereto and may be provided without electrical connection to perform solely an anchor function for improving bonding strength. In such a case, the pad portion (120) may extend horizontally on the build-up insulating portion and connect to the wiring portion provided thereon.

As illustrated in FIG. 1, when the protrusion (114) functions as a via portion for electrical connection with the build-up wiring portion, the protrusion (114) can electrically connect the pad portion (120) and the second wiring portion (122) disposed on the second insulating layer (112). Moreover, the direction of expansion of the protrusion (114), wherein the horizontal width varies along the vertical direction, may be identical to the direction of expansion of the plurality of via portions (130) disposed within the build-up insulating portion. However, this is not limiting, and as shown in FIG. 13, the direction of expansion of the protrusion (114) may differ from the direction of expansion of the plurality of via portions (130). For example, the first to third via portions (131, 132, 133) may have a shape wherein the horizontal width progressively increases as one moves downwards in the vertical direction. In this case, the protrusion (114) may have a shape where the horizontal width progressively decreases as it extends downward in the vertical direction. This may imply that the hole formation process for creating the protrusion (114) is performed using a different process from the hole formation process for creating the plurality of via portions (130). Accordingly, the warping characteristics of the circuit board (10) may be improved by the reverse-radius structure between the protrusion (114) and the plurality of via portions (130).

The protrusions (114) are provided in plurality and may be disposed along the horizontal direction of the insulating layer (110). At least some of the plurality of protrusions (114) may be disposed to overlap perpendicularly with the pad portion (120), the protective layer (190), the through portion (152), and the protrusion (156). At least one of the plurality of protrusions (114) may be disposed to overlap perpendicularly with the pad portion (120), the protective layer (190), the through portion (152), and the protruding portion (156). At least some of the plural protrusions (114) may be disposed to overlap perpendicularly with the hole (192) in the protective layer (190). The protrusions (114) overlapping perpendicularly with the hole (192) may also be understood as being disposed misaligned (offset) in the vertical direction relative to the protective layer (190).

As shown in FIG. 12, when a plurality of protrusions (114) comprise a first protrusion (114a) and two (2) second protrusions (114b) spaced apart horizontally from the first protrusion (114a), the first protrusion (114a) may be disposed to overlap perpendicularly with the through portion (152). The second protrusions (114b) may have a portion vertically overlapping the through portion (152) and a remaining portion disposed vertically offset from the through portion (152). For example, the second protrusion (114b) may comprise a first region (114c) vertically overlapping the pad portion (120), protective layer (190), and protrusion (156), and a second region (114d) vertically overlapping the pad portion (120), protrusion (156), and through hole (152).

The horizontal width of each protrusion (114) may be smaller than the horizontal width of the through portion (152). Consequently, if the horizontal width of the protrusion (114) within the insulating layer (110) is larger than the horizontal width of the through portion (152), it becomes difficult to achieve a fine pitch for the plurality of protrusions (114) within the insulating layer (110). Furthermore, as the horizontal width of the inner wall of the through portion within the insulating layer (110), which is the placement area for the protrusions (114), becomes shorter, the inner wall of the through portion may collapse.

Meanwhile, as illustrated in FIG. 12, the vertical thickness of the protrusion (114) may be identical to the vertical thickness of the insulating layer (110). However, this is not limiting; when a wiring portion is buried in an ETS structure on the lower surface of the insulating layer (110), and the wiring portion and the pad portion (120) are vertically connected via the protrusion (114), the vertical thickness of the protrusion (114) may be smaller than the vertical thickness of the insulating layer (110).

Moreover, as illustrated in FIGS. 14 to 17, the lower surface of the protrusion (114) may be spaced apart in the vertical direction from the lower surface of the insulating layer (110). In this case, the vertical thickness (t1) of the insulating layer (110) may be greater than the vertical thickness (t2) of the protrusion (114). In this case, the pad portion (120) and the second wiring portion (122) are not electrically connected by the protrusion (114). For example, as illustrated in FIG. 16, the vertical thickness (t2) of the protrusion (114) may be at least one-half of the vertical thickness (t1) of the insulating layer (110). Accordingly, the bonding strength of the bonding portion (150) with the insulating layer (110) and the protective layer (190) through the protrusion (114) may be improved.

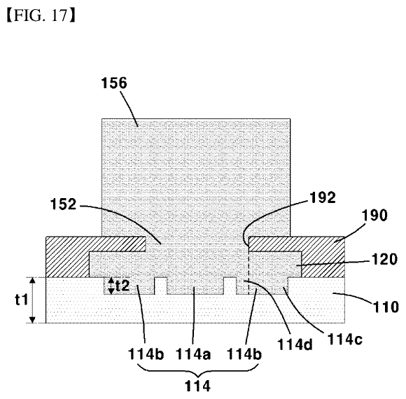

However, as shown in FIG. 17, the vertical thickness (t2) of the protrusion (114) may be less than half the vertical thickness (t1) of the insulating layer (110). In this case, the amount of plating required to form the protrusion (114) is reduced, and the machining process for the protrusion (114) can be more readily performed.

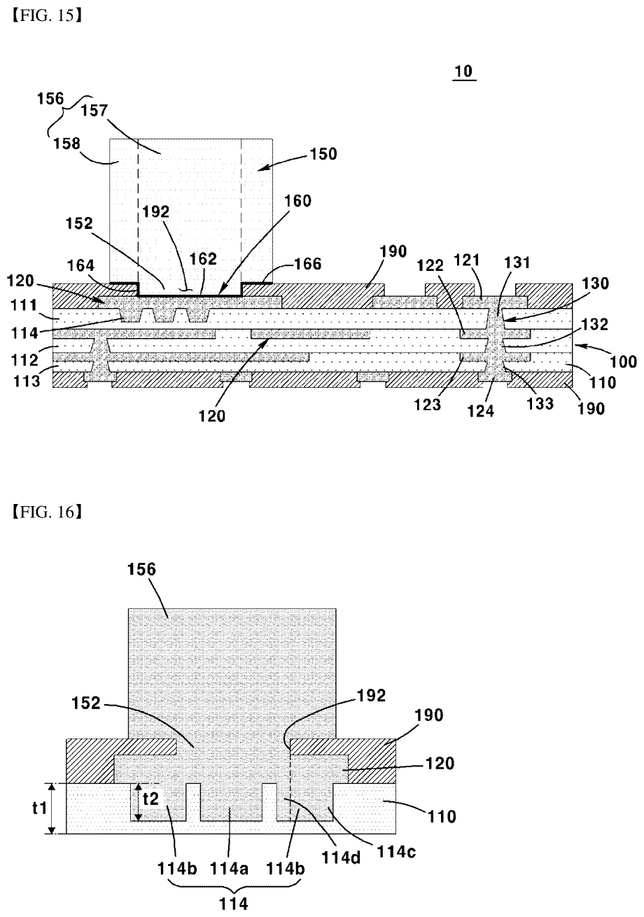

Furthermore, as the vertical thickness (t2) of the protrusion (114) is formed shorter than the vertical thickness (t1) of the insulating layer (110), even in a structure where electrical connection between the pad portion (120) and the second wiring portion (122) through the protrusion (114) is not established, the direction of enlargement, which is the shape where the horizontal width in the vertical direction of the protrusion (114) increases or decreases, may be the same as the direction of enlargement of the plurality of via holes (130) as shown in FIG. 14, but may also be opposite to the direction of enlargement of the plurality of via holes (130) as shown in FIG. 15.

Referring to FIG. 19, when a protrusion (114) is present and vertically overlaps the through [symbol] -hole (152), the vertical bonding structure between the pad portion (120) and the protrusion (114) increases the bonding strength of the bonding portion (150) on the circuit board (10). and between the pad portion (120) and the protrusion portion (114), thereby potentially increasing the bonding strength of the bonding portion (150) on the circuit board (10). That is, the bonding portion (150) forms a higher vertical bonding force with the pad portion (120) and protrusion portion (114) compared to the insulating layer (110) made of insulating material. Consequently, the horizontal shear strength of the bonding portion (150) on the circuit board (10) can be further increased. In summary, the shear strength of the bonding portion (150) itself may be increased through the protruding portion (114) vertically overlapping the through-hole (152).

Recently, in line with the trend towards higher performance and greater integration in semiconductor chips, the size of the bonding portion (150) connected to the semiconductor chip is also increasing as the chip size grows. Specifically, the vertical thickness of the bonding portion (150) is trending upwards; according to the embodiment, the vertical thickness of the bonding portion (150) may be 120 μm or more and 200 μm or less. If the vertical thickness of the bonding portion (150) is less than 120 μm, the distance secured in the vertical direction between the semiconductor chip and the circuit board (10) is insufficient. This presents disadvantages in terms of heat dissipation and the bonding process of the semiconductor chip onto the bonding portion. Should the vertical thickness of the bonding portion (150) exceed 200 μm, it becomes vulnerable to shear stress within the bonding portion (150) itself, posing a risk of fracture. Furthermore, increased plating volume leads to higher manufacturing costs. Within the aforementioned range, advantages are achieved in terms of securing sufficient distance from the semiconductor chip and enhancing the durability of the bonding portion (150) itself.

Furthermore, In the embodiment, the vertical thickness of the bonding portion (150) is formed to be greater than the vertical thickness of the insulating layer (110) in the placement area of the protrusion (114). This facilitates the bonding process and heat dissipation of the semiconductor chip. However, the issue of potentially reduced durability can be resolved through the aforementioned anchoring function of the protrusion (114).

Referring to FIG. 18, in the absence of a protrusion (114) vertically overlapping the through-hole (152), during fracture testing of the bonding portion (150), only the surface of the insulating layer (110) forms the fracture surface. However, when a protrusion (114) overlapping perpendicularly with the through hole (152) is present, it can be observed that holes corresponding to the number of protrusions (114) are formed on the upper surface of the insulating layer (110), which is the fracture surface of the bonding portion (150). This indicates that during the fracture process of the bonding portion (150), the protrusions (114) separated from the circuit board (10) together with the bonding portion (150).

Furthermore, referring to FIG. 20, it can be observed that as the number of protrusions (114) overlapping perpendicularly with the through portion (152) increases, the shear stress in the bonding portion (150) also increases. However, when the number of protrusions (114) vertically overlapping the through-hole (152) is four, it forms more than twice the shear strength compared to when no such protrusions exist. By arranging multiple protrusions (114) connected to a single pad portion (120) to overlap perpendicularly with the through portion (152), and considering the possibility of short-circuiting between multiple protrusions (114) or the collapse of the inner wall of the hole within the insulating layer (110) due to the reduction in the horizontal distance between multiple protrusions (114), it is desirable that the number of protrusions (114) vertically overlapping the through-hole (152) be four or fewer.

According to the embodiment, the vertical support structure via the protrusion (114) overlapping perpendicularly with the through hole (152) enables a more robust bonding of the bonding portion (150) onto the circuit board (10). Furthermore, as described above, it secures shear stress to improve the reliability of the protrusion (156) and and by including at least one of the aforementioned protrusions (114), wherein the horizontal width of the through hole (152) is provided to be 50% or more but not more than 90% of the horizontal width of the protrusion (156) for achieving fine pitch, the bonding portion and the build-up insulating portion can be bonded more robustly.

According to an embodiment, the protrusions (114) may be provided in plural numbers. Where provided in plural numbers, at least one of the protrusions (114) may include an area overlapping perpendicularly with the protrusion (156) and the protective layer (190). By positioning the protective layer (190), which has a different coefficient of thermal expansion, between the protrusion (156) and the protruding portion (114), stress can be mitigated and the bonding strength between the bonding portion (150) and the build-up insulation portion can be further enhanced.

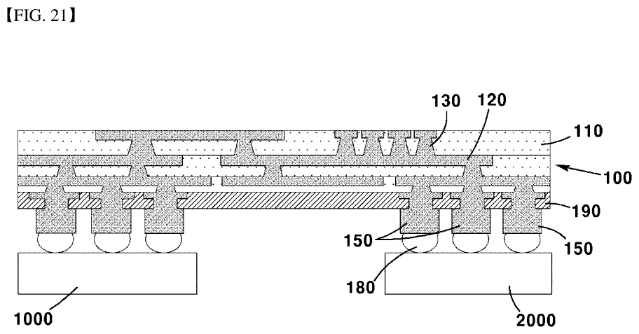

FIG. 21 is a cross-sectional view of a semiconductor package according to an embodiment of the present invention.

Referring to FIG. 21, a plurality of bonding regions (150) may be arranged on the surface of the circuit board (10). Multiple bonding sites (150) may accommodate semiconductor chips (1000, 2000). For example, a first semiconductor chip (1000) may be placed on some of the multiple bonding sites (150), whilst a second semiconductor chip (2000) may be placed on other bonding sites (150). The semiconductor chips (1000, 2000) possess terminals, and through connecting elements (180) such as solder balls or solder paste, the terminals and the surface of the bonding area (150) can be electrically and physically bonded.

The foregoing description of the components constituting the embodiments of the present invention as being combined or operating in combination does not imply that the invention is necessarily limited to these embodiments. That is to say, within the scope of the objectives of the present invention, all components may optionally be combined and operate in one or more ways. Furthermore, terms such as “include”, “comprise”, or “have” as described above, unless specifically stated otherwise, imply that the component may be present, and should therefore be interpreted as not excluding other components but rather as potentially including additional components. All terms, including technical or scientific terms, unless otherwise defined, have the same meaning as generally understood by a person skilled in the art to which the invention pertains. Commonly used terms, such as those defined in dictionaries, should be interpreted in accordance with their meaning in the context of the relevant technology and, unless explicitly defined herein, should not be interpreted in an idealized or overly formalistic sense.

The foregoing description merely exemplifies the technical concept of the present invention. Those skilled in the art to which the present invention pertains will appreciate that various modifications and variations may be made without departing from the essential character of the invention. Therefore, the embodiments disclosed herein are intended to illustrate the technical concept of the invention, not to limit it, and the scope of the technical concept of the invention is not restricted by these embodiments. The scope of protection of the invention shall be interpreted by the appended claims, and all technical concepts within the scope of these claims shall be interpreted as falling within the scope of the invention.

Meanwhile, when a circuit board possessing the aforementioned features of the invention is utilized in IT devices such as smartphones, server computers, or televisions, or in home appliances, it can reliably perform functions such as signal transmission or power supply. For example, when a circuit board possessing the features of the present invention performs a semiconductor package function, it can safely protect the semiconductor chip from external moisture or contaminants, and can resolve issues such as leakage current, electrical short circuits between terminals, or electrical open circuits in the terminals supplying the semiconductor chip. Furthermore, when responsible for signal transmission functions, it can resolve noise issues. Consequently, the circuit board possessing the aforementioned features of the invention enables the stable functioning of IT devices or home appliances, thereby achieving functional integrity or technical interconnectivity between the entire product and the circuit board incorporating the present invention.

When a circuit board possessing the aforementioned invention's features is utilized in transport devices such as vehicles, it can resolve signal distortion issues transmitted to the transport device, or safely protect the semiconductor chip controlling the transport device from external sources. It can also resolve issues such as leakage current, electrical short circuits between terminals, or electrical open circuits in terminals supplying the semiconductor chip, thereby further improving the transport device's stability. Therefore, the transport device and the circuit board incorporating the present invention can achieve functional integration or technical interlocking.

1. A circuit board, comprising:
an insulating layer;
a pad portion disposed on the insulating layer;
a protective layer disposed on the pad portion; and
a bonding portion disposed on the pad portion,
wherein the protective layer includes a hole penetrated in the vertical direction,
wherein the bonding portion includes a through portion disposed in the hole and a protrusion disposed on the through portion and having a width greater than a width of the through portion, and
wherein the width of the through portion is within the range of 50% or more to 90% or less of the width of the protrusion.

2. The circuit board of claim 1, wherein a surface of the protective layer is a plasma-treated area.

3. The circuit board of claim 2, wherein the protective layer includes a resin and a filler disposed within the resin, wherein the filler is not exposed to the surface of the resin.

4. The circuit board of claim 1, wherein a concave portion is disposed on the surface of the protective layer facing the bonding portion,
and a protrusion engaging with the concave portion is provided on the surface of the bonding portion facing the protective layer.

5. The circuit board of claim 3, wherein the concave portions and protrusions are provided in plural numbers, and the shape of each of the plural concave portions and each of the plural protrusions has a mutually different planar shape.

6. The circuit board of claim 1, wherein the horizontal width of the protrusion is smaller than the horizontal width of the pad portion.

7. The circuit board of claim 1, wherein the pad portion includes a plurality of protrusions penetrating at least a portion of the insulating layer from the lower surface of the pad portion, and at least one of the plurality of protrusions overlaps perpendicularly with the through portion.

8. The circuit board of claim 7, wherein the plural protrusions include a first protrusion and a plurality of second protrusions spaced apart horizontally from the first protrusion,
wherein the first protrusion overlaps the through portion perpendicularly, and wherein the second protrusions overlap the through portion perpendicularly at least in part, and the remaining portion thereof is misaligned perpendicularly from the through portion.

9. The circuit board of claim 7, wherein the number of the plural protrusions overlapping perpendicularly with the through portion is four or fewer.

10. The circuit board of claim 8, wherein the horizontal width of the first protrusion is smaller than the horizontal width of the through portion.

11. The circuit board of claim 8, wherein the protrusion includes a first region overlapped perpendicularly on the through portion and a second region misaligned perpendicularly from the through portion, and at least another portion of the second protrusion is overlapped perpendicularly with the second region.

12. The circuit board of claim 1, comprising a seed layer including
a first portion disposed on the pad portion, a second portion disposed on the inner wall of the hole, and a third portion disposed on the protective layer.

13. The circuit board of claim 12, wherein the size of the grains constituting the seed layer is larger than the size of the grains constituting the bonding portion.

14. The circuit board of claim 1, comprising: a fracture surface in which the bonding portion is separated through the fracture test applied with external force for separating the bonding portion, and the fracture surface includes a surface of the insulating layer exposed in the vertical direction.

15. The circuit board of claim 1, wherein a vertical thickness of the bonding portion is 120 μm or more and 200 μm or less.

16. A circuit board, comprising:
a build-up insulating portion including multiple insulating layers stacked in the vertical direction;
a pad portion disposed on the build-up insulating portion;
a protective layer disposed on the pad portion;
a bonding portion disposed on the protective layer and connected to the pad portion by penetrating the protective layer; and
a plurality of via electrodes disposed on the underside of the pad portion and penetrating at least a portion of the build-up insulating portion, wherein the bonding portion includes a through portion overlapping the protective layer in the horizontal direction and a protrusion disposed on the protective layer,
wherein a horizontal width of the through portion is at least 50% and at most 90% of a horizontal width of the protrusion, and
wherein at least some of the plurality of via electrodes are vertically overlapped with the pad portion, the protective layer, and the protrusion.

17. The circuit board of claim 16, wherein at least one of the plurality of via electrodes overlaps the pad portion, the protective layer, and the protrusion perpendicularly.

18. The circuit board of claim 16, wherein at least one of the plurality of via electrodes includes a first region vertically overlapping the pad portion, the protective layer, and the protrusion, and a second region vertically overlapping the pad portion, the protrusion, and the through portion.

19. The circuit board of claim 16, wherein at least one of the plurality of via electrodes is misaligned along a direction perpendicular to the protective layer.

20. The circuit board of claim 16, wherein a surface of the protective layer is a plasma-treated area.
